(19) United States
(12) Patent Application Publication
(10) Pub. No.: US 2026/0130123 A1
(43) Pub. Date: May 7, 2026

(54) Method for Preparing Quantum Device, and Superconducting Circuit and Quantum Chip

(71) Applicant: ALIBABA DAMO (HANGZHOU) TECHNOLOGY CO., LTD., Hangzhou, Zhejiang (CN)

(72) Inventors: Ran GAO, Hangzhou, Zhejiang (CN); Chunqing DENG, Hangzhou, Zhejiang (CN)

(21) Appl. No.: 19/117,357

(22) PCT Filed: Sep. 25, 2023
(86) PCT No.: PCT/CN2023/121264

§ 371 Date: Mar. 31, 2025

(30) Foreign Application Priority Data
Sep. 30, 2022 (CN) 202211215563.3

(51) Int. Cl. H10N 60/01; H10N 60/12; H10N 60/80

(52) U.S. Cl. CPC H10N 60/0912; H10N 60/12; H10N 60/805

(57) ABSTRACT

Disclosed in the present disclosure are a method for preparing a quantum device, and a superconducting circuit and a quantum chip. The method includes: sequentially obtaining a plurality of superconducting material layers in different regions of a substrate, wherein the plurality of superconducting material layers each include a superconducting material deposited on the substrate and a hard mask covering the corresponding superconducting material, and the superconducting materials in the plurality of superconducting material layers include a superconducting material having kinetics inductance; performing etching to remove the hard masks on the plurality of superconducting material layers, so as to obtain a plurality of target circuit elements integrated on the substrate; and preparing a target quantum device based on the plurality of target circuit elements. The present disclosure solves the technical problem of difficult preparation of a superconducting quantum device.

This present disclosure claims priority to Chinese Patent Application No. 202211215563.3 filed to the China National Intellectual Property Administration on Sep. 30, 2022 and entitled “Method for Preparing Quantum Device, and Superconducting Circuit and Quantum Chip”, the disclosure of which is hereby incorporated by reference in its entirety.

### TECHNICAL FIELD

The present disclosure relates to the field of superconducting quanta, and specifically, to a method for preparing a quantum device, and a superconducting circuit and a quantum chip.

### BACKGROUND

In the related art, the preparation of superconducting quantum bits using high inductance materials requires high preparation techniques and makes it difficult to realize the preparation of superconducting quantum devices.

Therefore, there is a technical problem of difficult preparation of a superconducting quantum device in the related art.

In view of the above problem, no effective solution has been proposed yet.

### SUMMARY

Embodiments of the present disclosure provide a method for preparing a quantum device, and a superconducting circuit and a quantum chip, so as to at least solve the technical problem of difficult preparation of a superconducting quantum device.

An aspect of an embodiment of the present disclosure provides a method for preparing a quantum device, including: sequentially obtaining a plurality of superconducting material layers in different regions of a substrate, wherein the plurality of superconducting material layers each include a superconducting material deposited on the substrate and a hard mask covering the corresponding superconducting material, and the superconducting materials in the plurality of superconducting material layers include superconducting materials having kinetics inductance; performing etching to remove the hard masks on the plurality of superconducting material layers, so as to obtain a plurality of target circuit elements integrated on the substrate; and preparing a target quantum device based on the plurality of target circuit elements.

As at least one alternative embodiment, wherein when the plurality of superconducting material layers are two superconducting material layers and the two superconducting material layers are a first superconducting material layer and a second superconducting material layer, sequentially obtaining the plurality of superconducting material layers in different regions of the substrate includes: depositing, on the substrate, the first superconducting material layer of a first superconducting material of a first target region range covered by a first hard mask of the first target region range, wherein the first superconducting material is the superconducting material having kinetics inductance; depositing a second superconducting material on the substrate deposited with the first superconducting material layer; covering a second hard mask on the second superconducting material; and etching the second hard mask and the second superconducting material to obtain a second superconducting material layer of the second superconducting material of a second target region range covered by the second hard mask of the second target region range.

As at least one alternative embodiment, wherein depositing, on the substrate, the first superconducting material layer of the first superconducting material of the first target region range covered by the first hard mask of the first target region range includes: depositing the first superconducting material on the substrate; covering the first hard mask on the first superconducting material; determining the first target region range of the first superconducting material that is to be remained on the substrate; and etching the first hard mask and the first superconducting material to obtain the first superconducting material layer of the first superconducting material of the first target region range covered by the first hard mask of the first target region range.

As at least one alternative embodiment, wherein etching the first hard mask and the first superconducting material to obtain the first superconducting material layer of the first superconducting material of the first target region range covered by the first hard mask of the first target region range includes: performing gradual etching to remove the first hard mask of a first other region range in the first hard mask and a superconducting material of a first other region in the first superconducting material, respectively, so as to obtain the first superconducting material layer of the first superconducting material of the first target region range covered by the first hard mask of the first target region range, wherein the first other region range is a region range on the substrate other than the first target region range.

As at least one alternative embodiment, wherein etching the second hard mask and the second superconducting material to obtain the second superconducting material layer of the second superconducting material of the second target region range covered by the second hard mask of the second target region range includes: performing gradual etching to remove the second hard mask of a second other region in the second hard mask and a superconducting material of the second other region in the second superconducting material, respectively, so as to obtain the second superconducting material layer of the second superconducting material of the second target region range covered by the second hard mask of the second target region range, wherein the second other region range is a region range on the substrate other than the second target region range.

As at least one alternative embodiment, wherein preparing the target superconducting device based on the plurality of target circuit elements includes: determining a junction region and an ohmic contact region on the substrate; and using a shadow evaporation method to evaporate and deposit a Josephson junction in the junction region and evaporate and deposit an ohmic contact in the ohmic contact region, so as to obtain a superconducting quantum bit as the target superconducting device.

As at least one alternative embodiment, wherein the superconducting quantum bit is a Fluxonium quantum bit.

As at least one alternative embodiment, wherein after depositing, on the substrate, the first superconducting material layer of the first superconducting material of the first target region range covered by the first hard mask of the first target region range, the method further includes: performing a high-temperature annealing treatment on the first superconducting material layer to obtain a target first superconducting material layer, wherein a kinetics inductance value of the first superconducting material in the target first superconducting material layer reaches a target kinetics inductance value.

As at least one alternative embodiment, wherein performing the high-temperature annealing treatment on the first superconducting material layer to obtain the target first superconducting material layer includes: selecting a target high-temperature annealing control parameter from a plurality of candidate high-temperature annealing control parameters; and performing the high-temperature annealing treatment on the first superconducting material layer based on the target high-temperature annealing control parameter, so as to obtain the target first superconducting material layer.

As at least one alternative embodiment, wherein performing etching to remove the first hard mask on the first superconducting material layer and the second hard mask on the second superconducting material layer, so as to obtain the target circuit elements integrated on the substrate includes: performing etching, by using a Hydrofluoric Acid (DHF) solution, to remove the first hard mask on the first superconducting material layer and the second hard mask on the second superconducting material layer, so as to obtain the target circuit elements integrated on the substrate.

As at least one alternative embodiment, wherein the hard mask is silicon nitride.

Another aspect of the present disclosure provides a method for preparing a Fluxonium quantum bit, including: depositing, on a substrate, a first superconducting material layer of a first superconducting material of a first target region range covered by a first hard mask of the first target region range, wherein the first superconducting material is a superconducting material having kinetics inductance; depositing a second superconducting material on the substrate deposited with the first superconducting material layer; covering a second hard mask on the second superconducting material; etching the second hard mask and the second superconducting material to obtain a second superconducting material layer of the second superconducting material of a second target region range covered by the second hard mask of the second target region range, wherein the second target region range includes a first sub-region range, a second sub-region range, and a third sub-region range, which are separate from each other; performing etching to remove the first hard mask on the first superconducting material layer and the second hard mask on the second superconducting material layer, so as to obtain the first superconducting materials integrated on the substrate that are located within the first target region range, and the second superconducting materials in the first sub-region range, second sub-region range, and third sub-region range; and depositing an ohmic contact between the first superconducting material and the second superconducting material within the first sub-region range, and depositing a Josephson junction between the second superconducting material within the second sub-region range and the second superconducting material within the third sub-region range, so as to obtain a Fluxonium quantum bit.

Another aspect of an embodiment of the present disclosure further provides a superconducting circuit, including a Fluxonium quantum bit prepared by the above method for preparing a Fluxonium quantum bit.

Yet another aspect of an embodiment of the present disclosure further provides a quantum chip, including a Fluxonium quantum bit prepared by the above method for preparing a Fluxonium quantum bit.

Still another aspect of an embodiment of the present disclosure further provides a quantum computer, including a quantum memory and the above quantum chip.

In the embodiments of the present disclosure, by means of using the superconducting material having the kinetics inductance as a material for preparing the target quantum device, and by integrating the plurality of superconducting materials having the kinetics inductance on the same substrate, solutions of preparing a quantum device using a large number of Josephson junctions in the related art are replaced, such that a purpose of reducing requirements for quantum device preparation conditions is achieved, thereby achieving a technical effect of large-scale integration of quantum bits, and solving the technical problem of difficult preparation of a superconducting quantum device.

### BRIEF DESCRIPTION OF THE DRAWINGS

The accompanying drawings described herein are used to provide a further understanding of the present disclosure, and constitute a part of the present disclosure. The exemplary embodiments of the present disclosure and the description thereof are used to explain the present disclosure, but do not constitute improper limitations to the present disclosure. In the drawings:

FIG. 1 is a flowchart of a method for preparing a quantum device according to an embodiment of the present disclosure.

FIG. 2 is a flowchart of a method for preparing a Fluxonium quantum bit according to an embodiment of the present disclosure.

FIG. 3 is a schematic diagram of synthesis according to an optional implementation of the present disclosure.

FIG. 4 is a schematic diagram I of photoetching patterning according to an optional implementation of the present disclosure.

FIG. 5 is a schematic diagram of wet etching according to an optional implementation of the present disclosure.

FIG. 6 is a schematic diagram of separation of two superconducting material layers according to an optional implementation of the present disclosure.

FIG. 7 is a schematic diagram II of photoetching printing according to an optional implementation of the present disclosure.

FIG. 8 is a schematic diagram of an etching process according to an optional implementation of the present disclosure.

FIG. 9 is a schematic diagram of wafer cleaning according to an optional implementation of the present disclosure.

FIG. 10 is a schematic diagram of formation of an ohmic contact and a non-linear Josephson junction according to an optional implementation of the present disclosure.

FIG. 11 is a schematic diagram of a preparation apparatus according to an optional implementation of the present disclosure.

FIG. 12 is a schematic structural diagram of a quantum computer according to an embodiment of the present disclosure.

### DETAILED DESCRIPTION OF THE EMBODIMENTS

In order to enable those skilled in the art to better understand the solutions of the present disclosure, the technical solutions in the embodiments of the present disclosure will be clearly and completely described below in combination with the drawings in the embodiments of the present disclosure. It is apparent that the described embodiments are only part of the embodiments of the present disclosure, not all the embodiments. Based on the embodiments in the present disclosure, all other embodiments obtained by those of ordinary skill in the art without creative work shall fall within the protection scope of the present disclosure.

It is to be noted that terms “first”, “second” and the like in the description, claims and the above mentioned drawings of the present disclosure are used for distinguishing similar objects rather than describing a specific sequence or a precedence order. It should be understood that the data used in such a way may be exchanged where appropriate, in order that the embodiments of the present disclosure described here can be implemented in an order other than those illustrated or described herein. In addition, terms “include” and “have” and any variations thereof are intended to cover non-exclusive inclusions. For example, it is not limited for processes, methods, systems, products or devices containing a series of steps or units to clearly list those steps or units, and other steps or units which are not clearly listed or are inherent to these processes, methods, products or devices may be included instead.

First, some of the nouns or terms or appearing in the course of the description of the embodiments of the present disclosure are applicable to the following explanations.

Heat budget is heat energy required for silicon exposure in a process. One of the objectives of a semiconductor process is to minimize the heat energy required by silicon. One factor that determines the conditions of most silicon-based semiconductor processes is to minimize the heat budget by cooling or shortening the time.

Etching is a fairly important step in a semiconductor manufacturing process, a microelectronic IC manufacturing process, and a micro-nano manufacturing process. Etching is a main process for patterning associated with photoetching. The so-called etching is, in fact, photoetching corrosion in a narrow understanding, and includes performing a photoetching exposure treatment on a photoresist through photoetching, and then performing, in other manners, a corrosion treatment to remove a portion required to be removed. Etching is a process of selectively removing an unwanted material from a surface of a silicon wafer by chemical or physical methods, with the basic objective of correctly replicating a mask pattern on the adhesive-coated silicon wafer. With the development of micro-manufacturing processes, etching, broadly speaking, has become a generic term for stripping and removing materials by solutions, reactive ions, or other mechanical manners, and has become a universal term for micro-machining manufacturing. The simplest and most commonly used classifications for etching are: dry etching and wet etching. It is apparent that the difference between dry etching and wet etching lies in the fact that wet etching uses a solvent or solution for etching. Wet etching is a pure chemical process that refers to the use of a chemical reaction between a solution and a pre-etched material to remove a portion that is not masked by a masking film material for the purpose of etching. Wet etching has the advantages of being good in selectivity, good in repeatability, high in productivity, simple in device, and low in cost. There are many types of dry etching, including light volatilization, gaseous corrosion, plasma corrosion, and the like. According to a type of a material etched, dry etching is mainly divided into three types: metal etching, dielectric etching, and silicon etching. Dielectric etching is used for the etching of dielectric materials, such as silicon dioxide. Dry etching has the advantages of being good in anisotropism, high in selection ratio, good in controllability, flexibility, and repeatability, safe in fine line operation, easy to realize automation, free of chemical waste liquid, and high in cleanliness, and does not introduce pollution during treatment.

A wafer is a silicon wafer used to manufacture a silicon semiconductor circuit, an original material of which is silicon. High purity polycrystalline silicon is dissolved and doped into silicon crystal seeds, and then slowly pulled out to form cylindrical monocrystalline silicon. A silicon crystal rod is ground, polished, and sliced to form the silicon wafer, also known as the wafer.

### Embodiment 1

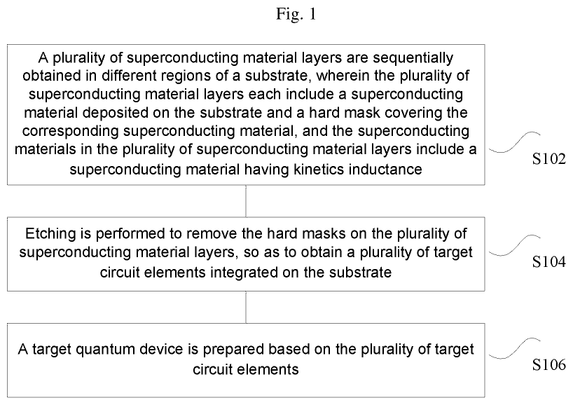

According to an embodiment of the present disclosure, a method for preparing a quantum device is provided. FIG. 1 is a flowchart of a method for preparing a quantum device according to an embodiment of the present disclosure. As shown in FIG. 1, the method includes the following steps.

At S102, a plurality of superconducting material layers are sequentially obtained in different regions of a substrate, wherein the plurality of superconducting material layers each include a superconducting material deposited on the substrate and a hard mask covering the corresponding superconducting material, and the superconducting materials in the plurality of superconducting material layers include a superconducting material having kinetics inductance.

At S104, etching is performed to remove the hard masks on the plurality of superconducting material layers, so as to obtain a plurality of target circuit elements integrated on the substrate.

At S106, a target quantum device is prepared based on the plurality of target circuit elements. Through the above steps, the method that may form the plurality of superconducting material layers in different regions of the substrate is applied to the preparation of the superconducting quantum device, that is, by combining the superconducting material having the kinetics inductance being used as a material for preparing the target quantum device with the above preparation method, the plurality of superconducting materials having the kinetics inductance are integrated on the same substrate, and solutions of preparing a quantum device using a large number of Josephson junctions in the related art are replaced, such that a purpose of reducing requirements for quantum device preparation conditions is achieved, thereby achieving a technical effect of large-scale integration of quantum bits, and solving the technical problem of difficult preparation of a superconducting quantum device.

As an optional embodiment, the superconducting materials used during the preparation of different quantum devices are different, and different superconducting materials differ not only in the superconducting materials themselves, but also in the number of the superconducting materials. Therefore, in order to meet preparation requirements for various superconducting quantum devices, it may be determined according to the superconducting materials required by the quantum devices to be prepared.

As an optional embodiment, when the plurality of superconducting material layers are sequentially obtained in different regions of the substrate, different quantum devices require different numbers of the superconducting material layers. In this embodiment, description is performed by using the plurality of superconducting material layers being two superconducting material layers as an example. The two superconducting material layers include a first superconducting material layer and a second superconducting material layer. It is to be noted that, the two superconducting material layers are only an example. According to the requirements of the quantum superconducting device, there may be three superconducting material layers, or may also be four superconducting material layers, etc. However, the method for preparing three superconducting material layers or four superconducting material layers is similar to the method for preparing two superconducting material layers, and a difference between the two methods lies in that the number of times for repeated operations is different.

For example, when the plurality of superconducting material layers are two superconducting material layers and the two superconducting material layers are a first superconducting material layer and a second superconducting material layer, sequentially obtaining the plurality of superconducting material layers in different regions of the substrate includes the following steps.

At S1022, the first superconducting material layer of a first superconducting material of a first target region range covered by a first hard mask of the first target region range is deposited on the substrate, wherein the first superconducting material is the superconducting material having kinetics inductance.

At S1024, a second superconducting material is deposited on the substrate deposited with the first superconducting material layer.

At S1026, a second hard mask is covered on the second superconducting material.

At S1028, the second hard mask and the second superconducting material are etched to obtain a second superconducting material layer of the second superconducting material of a second target region range covered by the second hard mask of the second target region range.

Through the above steps, the second superconducting material is deposited on the substrate deposited with the first superconducting material layer, the second hard mask is covered on the second superconducting material, and the second hard mask and the second superconducting material are etched to obtain the second superconducting material layer of the second superconducting material of the second target region range covered by the second hard mask of the second target region range (where the first target region range and the second target region range are different region ranges on the substrate). Therefore, the first superconducting material layer and the second superconducting material layer, that is, the two superconducting material layers, are obtained on the substrate. In the above preparation process, since the second superconducting material is deposited on the first superconducting material layer, and since the first superconducting material in the first superconducting material layer is covered by the first hard mask, when the second superconducting material layer is prepared, an impact on the first superconducting material layer can be effectively avoided, and the prepared superconducting quantum device is accurate.

It is to be noted that, the above substrate may be a wafer, for example, may be a silicon wafer or sapphire, etc. Furthermore, the above kinetics inductance is also referred to as dynamic inductance, which is relative to geometric inductance of a classical device. Geometric inductance is mainly determined based on a geometric shape and size of a device. The dynamic inductance is a special property exhibited by the quantum properties of the superconducting material. Therefore, when the quantum device is prepared, it is considered that the dynamic inductance is an important and necessary physical quantity, then the dynamic inductance is taken into consideration, and the corresponding superconducting quantum device is prepared based on the superconducting material having the dynamic inductance, such that the quantum device obtained through preparation can be more accurate.

As an optional embodiment, depositing, on the substrate, the first superconducting material layer of the first superconducting material of the first target region range covered by the first hard mask of the first target region range includes: the first superconducting material is deposited on the substrate; the first hard mask is covered on the first superconducting material; the first target region range of the first superconducting material that is to be remained on the substrate is determined; and the first hard mask and the first superconducting material are etched to obtain the first superconducting material layer of the first superconducting material of the first target region range covered by the first hard mask of the first target region range. The first hard mask and the first superconducting material are etched to obtain the first superconducting material layer of the first superconducting material of the first target region range covered by the first hard mask of the first target region range. Since the first superconducting material in the first superconducting material layer is covered by the first hard mask, the first superconducting material may be prevented from being affected when other superconducting material layers are obtained on the substrate subsequently, that is, the first superconducting material can be effectively protected in the process of preparing other superconducting material layers.

As mentioned above, the first target region range and the second target region range are different region ranges on the substrate. When the first target region range of the first superconducting material that is to be remained on the substrate is determined, as well as in the process of etching the second hard mask and the second superconducting material to obtain the second superconducting material layer of the second superconducting material of the second target region range covered by the second hard mask of the second target region range, and when the second target region range of the second superconducting material that is to be remained on the substrate needs to be determined, a target region range may be determined in various ways, for example, may be determined directly and manually, for example, in which position the superconducting material is prepared on the substrate is artificially determined, and a size of the target region range may be formulated according to a size of each circuit element when a target quantum bit is prepared previously. For another example, the size of the target region range may be determined based on a circuit design diagram, and when being determined based on the circuit design diagram, the size of the region range may be determined in the above manual manner, or may also be determined proportionally according to the circuit design diagram based on a computer.

As an optional embodiment, etching the first hard mask and the first superconducting material to obtain the first superconducting material layer of the first superconducting material of the first target region range covered by the first hard mask of the first target region range may include: gradual etching is performed to remove the first hard mask of a first other region range in the first hard mask and a superconducting material of the first other region in the first superconducting material, respectively, so as to obtain the first superconducting material layer of the first superconducting material of the first target region range covered by the first hard mask of the first target region range, wherein the first other region range is a region range on the substrate other than the first target region range. The above “gradual etching” may mean that the first hard mask of the first other region range in the first hard mask is etched first, and then the superconducting material of the first other region in the first superconducting material is etched.

After the first hard mask is covered on the first superconducting material deposited on the substrate, the first hard mask of the first other region range on the substrate in the first hard mask other than the first target region range, and the superconducting material of the first other region on the substrate in the first superconducting material other than the first target region range are respectively removed through gradual etching, such that the finally-obtained first superconducting material layer is a combination of the first superconducting materials of the first target region range covered by the first hard masks of the first target region range on the substrate.

It is to be noted that, when the first hard mask of the first other region range in the first hard mask is removed through etching, various manners may be used, for example, the first hard mask of the first other region range in the first hard mask may be removed through etching by means of combining photolithography and dry etching. When the superconducting material of the first other region in the first superconducting material is removed through etching, various manners may also be used, for example, the superconducting material of the first other region in the first superconducting material may be removed through etching by means of wet etching.

Therefore, by means of a combination of the manner of combining photolithography and dry etching and the manner of wet etching, deposition is performed sequentially on the substrate according to a type of a superconducting material to be integrated, a hard mask layer is covered thereon after the superconducting material is deposited each time, and after the first target region range and the first other region range are determined, the hard mask may be used to realize regional integration of the superconducting material on the substrate. The superconducting material within the first target region range needs to be remained, the first hard mask within the first other region range in the first hard mask is removed through etching by means of combining photolithography and dry etching, that is, only the first hard mask within the first target region range is remained, and then by means of wet etching, an etchant that can only dissolve the superconducting material but cannot dissolve the hard mask is used to remove the first superconducting material within the first other region range through etching, that is, only the first superconducting material within the first target region range is remained, thereby realizing the integration of the first superconducting material layer.

As an optional embodiment, etching the second hard mask and the second superconducting material to obtain the second superconducting material layer of the second superconducting material of the second target region range covered by the second hard mask of the second target region range includes: gradual etching is performed to remove the second hard mask of a second other region in the second hard mask and a superconducting material of the second other region in the second superconducting material, respectively, so as to obtain the second superconducting material layer of the second superconducting material of the second target region range covered by the second hard mask of the second target region range, where the second other region range is a region range on the substrate other than the second target region range.

Likewise, when the second hard mask of the second other region in the second hard mask is removed through etching, the second hard mask of the second other region in the second hard mask may also be removed through etching by means of combining photolithography and dry etching. When the superconducting material of the second other region in the second superconducting material is removed through etching, the superconducting material of the second other region in the second superconducting material may also be removed through etching by means of wet etching.

When the hard mask is removed by means of combining photolithography and dry etching, the hard mask may be patterned first by using photolithography, that is, to determine a pattern region of the hard mask to be removed, and then the hard mask to be removed based on the determined pattern region by using dry etching.

It is to be noted that, the above fact that the first superconducting material layer and the second superconducting material layer are deposited on the substrate is only an example. According to specific deposition requirements, or subsequent use of the substrate to manufacture different superconducting devices, more types of superconducting material layers may also be deposited on the substrate, and are not illustrated herein.

Furthermore, when the quantum device is prepared, different superconducting materials may be integrated on the same substrate. Different superconducting materials may all be deposited and etched in the same manner, and after regional integration of all the required superconducting materials is completed, the etchant that can only dissolve the hard mask but cannot dissolve the superconducting material may be used uniformly to etch the hard mask, so as to remove the hard mask and only remain various superconducting materials that are integrated.

As an optional embodiment, preparing the target superconducting device based on the plurality of target circuit elements includes: a junction region and an ohmic contact region on the substrate are determined; and a shadow evaporation method is used to evaporate and deposit a Josephson junction in the junction region and evaporate and deposit an ohmic contact in the ohmic contact region, so as to obtain a superconducting quantum bit as the target superconducting device. The Josephson junction may be obtained through manufacturing using a shadow evaporation technology, and the ohmic contact may be formed together with the manufacturing of the Josephson junction. In the process of shadow evaporation, a first evaporation layer is configured to form a first layer of the Josephson junction and the ohmic contact, and after evaporation and deposition of the first layer are completed, oxygen is introduced into a process chamber to complete oxidization of a metal surface, such that an insulation layer required by the Josephson junction is prepared. After oxidization is completed, a second evaporation layer is completed at different evaporation angles, so as to form the Josephson junction at an overlapping part of a first metal layer and a second metal layer.

As an optional embodiment, the superconducting quantum bit may be various types of quantum bits, for example, may be a Fluxonium quantum bit.

As an optional embodiment, after depositing, on the substrate, the first superconducting material layer of the first superconducting material of the first target region range covered by the first hard mask of the first target region range, the method further includes: a high-temperature annealing treatment is performed on the first superconducting material layer to obtain a target first superconducting material layer, where a kinetics inductance value of the first superconducting material in the target first superconducting material layer reaches a target kinetics inductance value.

After wet etching, whether the high-temperature annealing treatment needs to be performed on a material stack may be selected according to whether an attribute of the current material stack needs to be changed. Through the high-temperature annealing treatment, the performance of the first superconducting material layer or the surface performance of the substrate may be modified and adjusted, for example, a kinetics inductance value of the first superconducting material layer may be adjusted. In the embodiments of the present disclosure, performance adjustment is selected after wet etching, such that the problem of increased difficulty in wet etching caused by prioritizing of performance adjustment may also be avoided. It is to be noted that, by means of performing the high-temperature annealing treatment on the first superconducting material layer after the first superconducting material layer of the first superconducting material of the first target region range covered by the first hard mask of the first target region range is deposited on the substrate, compared to adjustment of the first superconducting material to required performance before the first superconducting material is deposited, since a preparation operation of treating the first superconducting material may cause certain damages to the material itself, leading to changes in the performance to affect the accuracy of the prepared device, after the first superconducting material is deposited, that is, the entire first superconducting material layer is adjusted to required target performance after the preparation operation completes, the required first superconducting material can meet an expected performance requirement.

As an optional embodiment, performing the high-temperature annealing treatment on the first superconducting material layer to obtain the target first superconducting material layer includes: a target high-temperature annealing control parameter is selected from a plurality of candidate high-temperature annealing control parameters; and the high-temperature annealing treatment is performed on the first superconducting material layer based on the target high-temperature annealing control parameter, so as to obtain the target first superconducting material layer. Performing the high-temperature annealing treatment on the first superconducting material layer may realize performance adjustment of the first superconducting material layer. To what extent the performance of the first superconducting material layer is specifically adjusted (for example, the kinetics inductance of the first superconducting material layer is adjusted to the target kinetics inductance value), implementation may be achieved by adjusting the target high-temperature annealing control parameter during high-temperature annealing, for example, a temperature, a heating duration, etc. during high-temperature annealing may be adjusted. It is to be noted that, when the target high-temperature annealing control parameter is selected from the plurality of candidate high-temperature annealing control parameters, the dynamic inductance of the first superconducting material of the first superconducting material layer may be as large as possible after the high-temperature annealing treatment is performed on the first superconducting material layer according to the selected high-temperature annealing control parameter, thereby meeting the performance requirement of the quantum device.

As an optional embodiment, performing etching to remove the first hard mask on the first superconducting material layer and the second hard mask on the second superconducting material layer, so as to obtain the target circuit elements integrated on the substrate includes: etching is performed, by using a DHF solution, to remove the first hard mask on the first superconducting material layer and the second hard mask on the second superconducting material layer, so as to obtain the target circuit elements integrated on the substrate. The DHF solution can only dissolve the hard mask but cannot dissolve the superconducting material, such that after various superconducting materials on the substrate are all correspondingly deposited and etched, the DHF solution may be used as an etchant, and wet etching is performed again on the first hard mask and the second hard mask on the superconducting material layer, so as to finally remove the hard mask on the superconducting material layer, thereby obtaining the target circuit elements finally integrated on the substrate. The wet etching method is used, that is, the hard masks on the first superconducting material layer and the second superconducting material layer are removed through etching by means of using the solution etchant. Compared to the manner of performing etching by using a photoresist, since the solution etchant can immerse into each edge of the hard mask in contact with the superconducting material, the hard mask in a gap between the edges of the superconducting materials can be removed more thoroughly, such that the first superconducting material and the second superconducting material integrated on the substrate are purer, thereby providing bases for subsequent preparation of an accurate superconducting device.

As an optional embodiment, the above first hard mask and second hard mask may be various types of nitrides, for example, may be silicon nitride.

An embodiment of the present disclosure further provides a preparation method embodiment of a method for preparing a Fluxonium quantum bit. FIG. 2 is a flowchart of a method for preparing a Fluxonium quantum bit according to an embodiment of the present disclosure. As shown in FIG. 2, the method includes the following steps.

At S202, the first superconducting material layer of a first superconducting material of a first target region range covered by a first hard mask of the first target region range is deposited on the substrate, where the first superconducting material is the superconducting material having kinetics inductance.

At S204, a second superconducting material is deposited on the substrate deposited with the first superconducting material layer.

At S206, a second hard mask is covered on the second superconducting material.

At S208, the second hard mask and the second superconducting material are etched to obtain a second superconducting material layer of the second superconducting material of a second target region range covered by the second hard mask of the second target region range, where the second target region range includes a first sub-region range, a second sub-region range, and a third sub-region range, which are separate from each other.

At S210, etching is performed to remove the first hard mask on the first superconducting material layer and the second hard mask on the second superconducting material layer, so as to obtain the first superconducting materials integrated on the substrate that are located within the first target region range, and the second superconducting materials in the first sub-region range, second sub-region range, and third sub-region range.

At S212, an ohmic contact is deposited between the first superconducting material and the second superconducting material within the first sub-region range, and depositing a Josephson junction between the second superconducting material within the second sub-region range and the second superconducting material within the third sub-region range, so as to obtain a Fluxonium quantum bit.

Through the above manners, the plurality of superconducting material layers, which are the first superconducting material layer and the second superconducting material layer, configured to prepare the Fluxonium quantum bit are sequentially obtained in different regions of the substrate. The second superconducting material layer is located within three different sub-region ranges, and after the corresponding superconducting material is obtained within the corresponding region range, the target circuit elements, which are the ohmic contact and the Josephson junction, configured to prepare the Fluxonium quantum bit are generated between the superconducting material layers, thereby obtaining the target quantum device, which is the Fluxonium quantum bit. Through the above manners, compared to a conventional method (which needs to integrate a large number of Josephson junctions) for preparing a Fluxonium quantum bit, the preparation method may integrate an inductive material having kinetics inductance as large as possible, such that a preparation difficulty can be effectively reduced, and preparation efficiency and accuracy can also be effectively improved.

Based on the above embodiments and optional embodiments, the present disclosure provides an optional implementation, which is described below.

The Fluxonium quantum bit is a very promising superconducting quantum computing bit implementation solution, and has the characteristics of being long in coherence time and large in anharmonicity between a calculated energy level and a non-calculated energy level. In order to use the Fluxonium quantum bit to implement general quantum computing, a quantum circuit having a large number of physical Fluxonium quantum bits (over thousands of quantum bits), a high process yield, and accurate bit parameter control needs to be constructed, which is also a great challenge in the field of quantum computing. Based on this, an optional implementation of the present disclosure develops an expandable material having kinetics inductance to implement a method for manufacturing a Fluxonium quantum bit with a low microwave loss. The method includes: preparation of a high kinetics inductance circuit element, integration of low inductive materials, and integration of non-linear circuit elements. The method has the characteristics of being good in material uniformity, high in process compatibility, large in heat budget, etc.

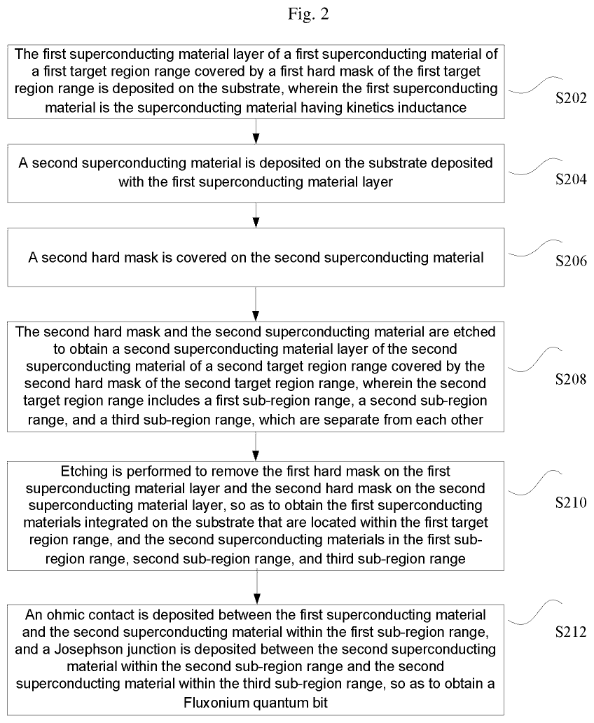

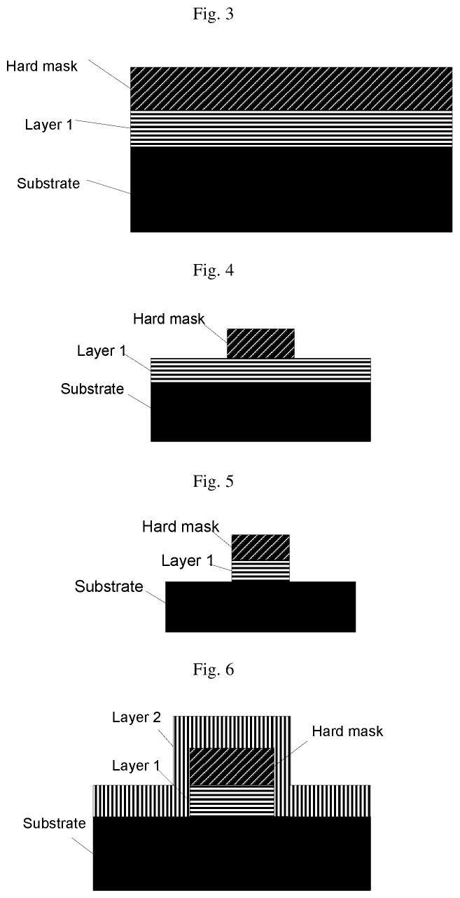

A process flow of the optional implementation of the present disclosure is as follows. FIG. 3 is a schematic diagram of synthesis according to an optional implementation of the present disclosure. First, a material (layer1 (Layer 1) in the figure) having kinetics inductance is synthesized on a bare wafer. Next, a hard mask is covered on the Layer 1 for subsequent photoetching patterning and dry etching (Dielectric mask (hard mask) in the figure). FIG. 4 is a schematic diagram I of photoetching patterning according to an optional implementation of the present disclosure. The dry etching technology is used for etching the hard mask. The Layer 1 material may be used as an etching stop layer during etching, which is configured to protect a surface of the substrate. FIG. 5 is a schematic diagram of wet etching according to an optional implementation of the present disclosure. After the patterning of the hard mask is completed, wet etching is performed on the first superconducting material layer (Layer 1) (a wet etchant has a large etching selection ratio to the first material layer and the hard mask material). After wet etching, there is an optional step, and an application may be selected according to whether an attribute of a material stack needs to be modified. For example, high-temperature annealing may be performed on a current material stack to adjust the performance of the first material layer or modify the surface performance of a base plate for subsequent process steps. The hard mask layer is generally suitable for high-temperature treatments, and may be remained during treatment for subsequent process steps.

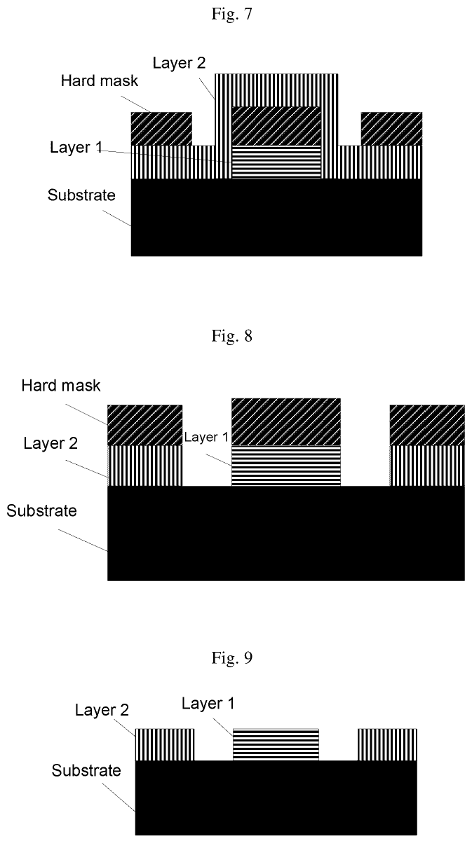

Next, the wafer is sent to deposit the second superconducting material layer (layer2 (Layer 2) in the figure). An important point here is that the hard mask is not removed throughout the process after the first layer is patterned, but is configured to separate the two superconducting material layers (FIG. 6 is a schematic diagram of separation of two superconducting material layers according to an optional implementation of the present disclosure). After the second superconducting material layer is deposited, another hard mask layer is deposited, and the patterning of the second superconducting material layer is completed by using a step similar to that of patterning the first material layer (FIG. 7 is a schematic diagram II of photoetching printing according to an optional implementation of the present disclosure). First, the hard mask is patterned through photolithography and dry etching to expose a portion of the second superconducting material layer that needs to be etched, and then a second material layer is etched by using a wet etching technology. Due to the protection of a first dielectric layer, the first material layer is intact and unaffected during etching (FIG. 8 is a schematic diagram of an etching process according to an optional implementation of the present disclosure). The necessity of using wet etching in this step lies in that, isotropic etching facilitates the complete removing of the second material layer that may remain around an edge of the first material layer. After the etching step is completed, the wafer is cleaned in an acidic solution (DHF) to remove the hard mask layer, and the superconducting material is not affected in this step (FIG. 9 is a schematic diagram of wafer cleaning according to an optional implementation of the present disclosure).

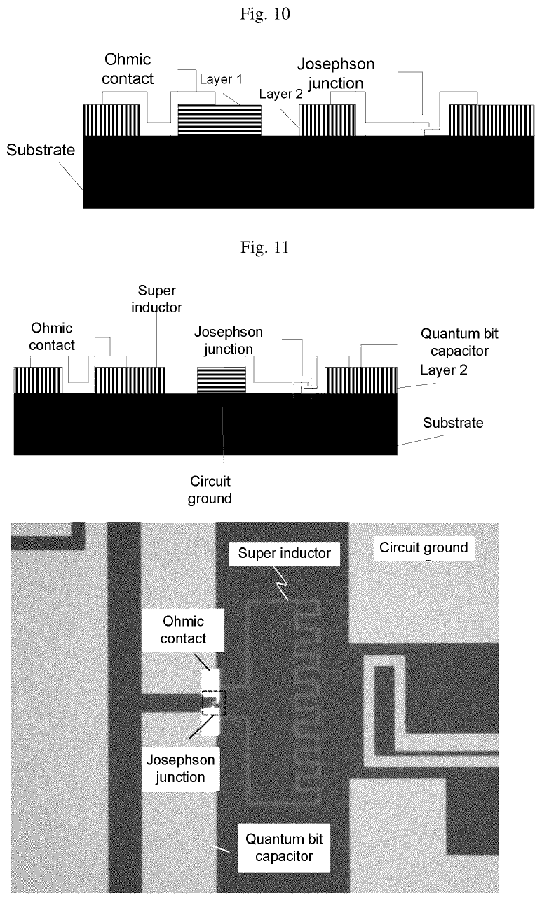

After the first material layer and the second material layer on the wafer are formed, that is, after a linear circuit element of a Fluxonium quantum bit is formed, the last step is to form a necessary ohmic contact and a non-linear Josephson junction (FIG. 10 is a schematic diagram of formation of an ohmic contact and a non-linear Josephson junction according to an optional implementation of the present disclosure). The Josephson junction may be manufactured by using a shadow evaporation technology, and the ohmic contact may also be formed together with the manufacturing of the non-linear Josephson junction. In short, at exposed parts of a junction region and an ohmic contact region of the wafer, regional metal deposition is realized by using a double-layer photoresist. During shadow evaporation, a first evaporation layer forms a first layer for forming the Josephson junction and the ohmic contact. After evaporation and deposition of the first layer are completed, oxygen is introduced into a process chamber to complete oxidization of a metal surface, such that an insulation layer required by the Josephson junction is prepared. After oxidization is completed, a second evaporation layer is completed at different evaporation angles, so as to form the Josephson junction at an overlapping part between a first metal layer and a second metal layer.

FIG. 11 is a schematic diagram of a superconducting quantum bit prepared by a preparation method according to an optional implementation of the present disclosure. Various types of circuit elements in the superconducting quantum bit are marked and shown in the figure. In the figure, it may be seen that a typical Fluxonium includes three different materials marked as three different key circuit elements, that is, a super inductor (formed by the first superconducting material layer), a quantum bit capacitor, and a circuit ground (formed by the second superconducting material layer), and the Josephson junction and the ohmic contact are generally manufactured by aluminum layers.

It is to be noted that, for ease of simple description, the foregoing method embodiments are all expressed as a series of action combinations, but those skilled in the art should know that the present disclosure is not limited by the described action sequence, as according to the present disclosure, some steps may be performed in other sequences or simultaneously. Then, those skilled in the art should also know that the embodiments described in the specification are all preferred embodiments, and the actions and modules involved are not necessarily required by the present disclosure.

### Embodiment 2

An embodiment of the present disclosure further provides a quantum device, including a Fluxonium quantum bit prepared by the above method for preparing a Fluxonium quantum bit.

An embodiment of the present disclosure further provides a superconducting circuit, including a Fluxonium quantum bit prepared by the above method for preparing a Fluxonium quantum bit.

An embodiment of the present disclosure further provides a quantum chip, including a Fluxonium quantum bit prepared by the above method for preparing a Fluxonium quantum bit.

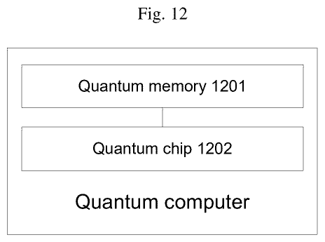

An embodiment of the present disclosure further provides a quantum computer. FIG. 12 is a schematic structural diagram of a quantum computer according to an embodiment of the present disclosure. The quantum computer may be any one of quantum computer devices in a quantum computer group. As shown in FIG. 12, the quantum computer includes a quantum memory 1201 and the above quantum chip 1202.

Those skilled in the art may understand that the structure shown in FIG. 12 is only a schematic diagram, which does not limit the structure of the above electronic apparatus. For example, the quantum computer may further include more or less components than those shown in FIG. 12, or have a different configuration from that shown in FIG. 12.

Those of ordinary skill in the art may understand that, all or part of the steps in the various methods of the above embodiments may be completed by instructing related preparation hardware through a program. The program may be stored in a computer-readable storage medium, and the storage medium may include a flash disk, a Read-Only Memory (ROM), a Random Access Memory (RAM), a magnetic disk, or an optical disk.

The serial numbers of the foregoing embodiments of the present disclosure are merely for description, and do not represent the superiority or inferiority of the embodiments.

In the above embodiments of the present disclosure, the description of the embodiments has its own focus. For parts that are not described in detail in a certain embodiment, reference may be made to related descriptions of other embodiments.

In the several embodiments provided in the present disclosure, it should be understood that, the disclosed technical content can be implemented in other ways. The above described embodiments are merely illustrative. The entire implementation process of the above embodiments also needs to be completed by combining a control program unit of a computer. The division of units is only a logical function division, and there may be other divisions in actual implementation. For example, a plurality of units or components may be combined or integrated into another system, or some features can be ignored, or not implemented. In addition, the displayed or discussed mutual coupling or direct coupling or communication connection may be indirect coupling or communication connection through some interfaces, units or modules, and may be in electrical or other forms.

The units described as separate components may or may not be physically separated. The components displayed as units may or may not be physical units, that is, the components may be located in one place, or may be distributed on the plurality of network units. Part or all of the units may be selected according to actual requirements to achieve the purposes of the solutions of this embodiment.

In addition, the functional units in the various embodiments of the present disclosure may be integrated into one processing unit, or each unit may exist alone physically, or two or more than two units may be integrated into one unit. The above integrated unit can be implemented in the form of hardware, or can be implemented in the form of a software functional unit.

If the integrated unit is implemented in the form of the software functional unit and sold or used as an independent product, it can be stored in the computer readable storage medium. Based on this understanding, the technical solutions of the present disclosure essentially or the parts that contribute to the related art, or all or part of the technical solutions can be embodied in the form of a software product. The computer software product is stored in a storage medium, including a plurality of instructions for causing a computer device (which may be a personal computer, a server, or a network device, and the like) to execute all or part of the steps of the method described in the various embodiments of the present disclosure. The foregoing storage medium includes a USB flash disk, a Read-Only Memory (ROM), a Random Access Memory (RAM), and various media that can store program codes, such as a mobile hard disk, a magnetic disk, or an optical disk.

The above description is merely preferred implementation of the present disclosure, and it should be noted that those of ordinary skill in the art may also make several improvements and refinements without departing from the principle of the present disclosure, and it should be considered that these improvements and refinements shall all fall within the protection scope of the present disclosure.

What is claimed is:

1. A method for preparing a quantum device, comprising:
sequentially obtaining a plurality of superconducting material layers in different regions of a substrate, wherein the plurality of superconducting material layers each include a superconducting material deposited on the substrate and a hard mask covering the corresponding superconducting material, and the superconducting materials in the plurality of superconducting material layers include superconducting materials having kinetics inductance;
performing etching to remove the hard masks on the plurality of superconducting material layers, so as to obtain a plurality of target circuit elements integrated on the substrate; and
preparing a target quantum device based on the plurality of target circuit elements.

2. The method as claimed in claim 1, wherein when the plurality of superconducting material layers are two superconducting material layers and the two superconducting material layers are a first superconducting material layer and a second superconducting material layer, sequentially obtaining the plurality of superconducting material layers in different regions of the substrate includes:
depositing, on the substrate, the first superconducting material layer of a first superconducting material of a first target region range covered by a first hard mask of the first target region range, wherein the first superconducting material is the superconducting material having kinetics inductance;
depositing a second superconducting material on the substrate deposited with the first superconducting material layer;
covering a second hard mask on the second superconducting material; and
etching the second hard mask and the second superconducting material to obtain a second superconducting material layer of the second superconducting material of a second target region range covered by the second hard mask of the second target region range.

3. The method as claimed in claim 2, wherein depositing, on the substrate, the first superconducting material layer of the first superconducting material of the first target region range covered by the first hard mask of the first target region range includes:
depositing the first superconducting material on the substrate;
covering the first hard mask on the first superconducting material;
determining the first target region range of the first superconducting material that is to be remained on the substrate; and
etching the first hard mask and the first superconducting material to obtain the first superconducting material layer of the first superconducting material of the first target region range covered by the first hard mask of the first target region range.

4. The method as claimed in claim 3, wherein etching the first hard mask and the first superconducting material to obtain the first superconducting material layer of the first superconducting material of the first target region range covered by the first hard mask of the first target region range includes:
performing gradual etching to remove the first hard mask of a first other region range in the first hard mask and a superconducting material of a first other region in the first superconducting material, respectively, so as to obtain the first superconducting material layer of the first superconducting material of the first target region range covered by the first hard mask of the first target region range, wherein the first other region range is a region range on the substrate other than the first target region range.

5. The method as claimed in claim 2, wherein etching the second hard mask and the second superconducting material to obtain the second superconducting material layer of the second superconducting material of the second target region range covered by the second hard mask of the second target region range includes:
performing gradual etching to remove the second hard mask of a second other region in the second hard mask and a superconducting material of the second other region in the second superconducting material, respectively, so as to obtain the second superconducting material layer of the second superconducting material of the second target region range covered by the second hard mask of the second target region range, wherein the second other region range is a region range on the substrate other than the second target region range.

6. The method as claimed in claim 1, wherein preparing the target superconducting device based on the plurality of target circuit elements includes:
determining a junction region and an ohmic contact region on the substrate; and
using a shadow evaporation method to evaporate and deposit a Josephson junction in the junction region and evaporate and deposit an ohmic contact in the ohmic contact region, so as to obtain a superconducting quantum bit as the target superconducting device.

7. The method as claimed in claim 6, wherein the superconducting quantum bit is a Fluxonium quantum bit.

8. The method as claimed in claim 2, wherein after depositing, on the substrate, the first superconducting material layer of the first superconducting material of the first target region range covered by the first hard mask of the first target region range, the method further includes:
performing a high-temperature annealing treatment on the first superconducting material layer to obtain a target first superconducting material layer, wherein a kinetics inductance value of the first superconducting material in the target first superconducting material layer reaches a target kinetics inductance value.

9. The method as claimed in claim 8, wherein performing the high-temperature annealing treatment on the first superconducting material layer to obtain the target first superconducting material layer includes:
selecting a target high-temperature annealing control parameter from a plurality of candidate high-temperature annealing control parameters; and
performing the high-temperature annealing treatment on the first superconducting material layer based on the target high-temperature annealing control parameter, so as to obtain the target first superconducting material layer.

10. The method as claimed in claim 2, wherein performing etching to remove the first hard mask on the first superconducting material layer and the second hard mask on the second superconducting material layer, so as to obtain the target circuit elements integrated on the substrate includes:
performing etching, by using a Hydrofluoric Acid (DHF) solution, to remove the first hard mask on the first superconducting material layer and the second hard mask on the second superconducting material layer, so as to obtain the target circuit elements integrated on the substrate.

11. The method as claimed in any one of claims 1, wherein the hard mask is silicon nitride.

12. A method for preparing a Fluxonium quantum bit, comprising:
depositing, on a substrate, a first superconducting material layer of a first superconducting material of a first target region range covered by a first hard mask of the first target region range, wherein the first superconducting material is a superconducting material having kinetics inductance;
depositing a second superconducting material on the substrate deposited with the first superconducting material layer;
covering a second hard mask on the second superconducting material;
etching the second hard mask and the second superconducting material to obtain a second superconducting material layer of the second superconducting material of a second target region range covered by the second hard mask of the second target region range, wherein the second target region range includes a first sub-region range, a second sub-region range, and a third sub-region range, which are separate from each other;
performing etching to remove the first hard mask on the first superconducting material layer and the second hard mask on the second superconducting material layer, so as to obtain the first superconducting materials integrated on the substrate that are located within the first target region range, and the second superconducting materials in the first sub-region range, second sub-region range, and third sub-region range; and
depositing an ohmic contact between the first superconducting material and the second superconducting material within the first sub-region range, and depositing a Josephson junction between the second superconducting material within the second sub-region range and the second superconducting material within the third sub-region range, so as to obtain a Fluxonium quantum bit.

13-14. (canceled)

15. A quantum computer, including a quantum memory and the quantum chip, wherein the quantum chip including the Fluxonium quantum bit prepared by the following actions:
depositing, on a substrate, a first superconducting material layer of a first superconducting material of a first target region range covered by a first hard mask of the first target region range, wherein the first superconducting material is a superconducting material having kinetics inductance;
depositing a second superconducting material on the substrate deposited with the first superconducting material layer;
covering a second hard mask on the second superconducting material;
etching the second hard mask and the second superconducting material to obtain a second superconducting material layer of the second superconducting material of a second target region range covered by the second hard mask of the second target region range, wherein the second target region range includes a first sub-region range, a second sub-region range, and a third sub-region range, which are separate from each other;
performing etching to remove the first hard mask on the first superconducting material layer and the second hard mask on the second superconducting material layer, so as to obtain the first superconducting materials integrated on the substrate that are located within the first target region range, and the second superconducting materials in the first sub-region range, second sub-region range, and third sub-region range; and
depositing an ohmic contact between the first superconducting material and the second superconducting material within the first sub-region range, and depositing a Josephson junction between the second superconducting material within the second sub-region range and the second superconducting material within the third sub-region range, so as to obtain a Fluxonium quantum bit.

16. The method as claimed in claim 2, wherein the hard mask is silicon nitride.

17. The method as claimed in claim 3, wherein the hard mask is silicon nitride.

18. The method as claimed in claim 4, wherein the hard mask is silicon nitride.

19. The method as claimed in claim 5, wherein the hard mask is silicon nitride.

20. The method as claimed in claim 6, wherein the hard mask is silicon nitride.

21. The method as claimed in claim 7, wherein the hard mask is silicon nitride.

22. The method as claimed in claim 8, wherein the hard mask is silicon nitride.
